(19) United States
(12) Patent Application Publication
(10) Pub. No.: US 2026/0178802 A1
(43) Pub. Date: Jun. 25, 2026

(54) COMPUTER-IMPLEMENTED METHOD FOR PETROPHYSICAL MODELING WITH SIMULTANEOUS INCORPORATION OF HYDROGEN AND CHLORINE RESPONSES OBTAINED BY NUCLEAR SPECTROSCOPY LOGS AND COMPUTER-READABLE NON-TRANSIENT STORAGE MEDIUM

(71) Applicant: FETRÓLEO BRASILEIRO S.A. - PETROBRAS, Rio de Janeiro (BR)

(72) Inventor: Gabriel Do Nascimento Freitas, Rio de Janeiro (BR)

(21) Appl. No.: 19/424,662

(22) Filed: Dec. 18, 2025

(30) Foreign Application Priority Data
Dec. 23, 2024 (BR) 1020240271270

(51) Int. Cl. G06F 30/28

(52) U.S. Cl. CPC G06F 30/28

(57) ABSTRACT

The present invention describes a petrophysical modeling method that integrates well nuclear spectroscopy data and interpretations with some input petrophysical parameters, decomposing the hydrogen and chlorine signals into their specific origins, such as well drilling fluid, kerogen, water, and hydrocarbons in the pores. The model consists of a set of equations that are solved sequentially with input values defined by Monte Carlo simulation, from which properties such as salinity, porosity, density, sigma, and hydrogen index of the kerogen are calculated. The acceptability of such results is verified by comparison with logs such as density, porosity by NMR, and macroscopic cross section of thermal neutron capture.

### RELATED APPLICATIONS

This application claims the benefit of priority to Brazilian patent application Ser. No. 1020240271270, filed Dec. 23, 2024, the entire contents of which are incorporated herein by reference.

### FIELD OF THE INVENTION

The present invention pertains to the technical field of petrophysics, in the oil and natural gas exploration and production sector. More specifically, the proposed method is applicable in well log analysis activities and in the characterization of geological formations, focusing on improving the precision of estimates of petrophysical properties such as porosity, saturation, and organic content in reservoirs. The invention is particularly useful in logging and modeling operations of rock formations during hydrocarbon exploration, assisting in obtaining more precise data for decision-making in industrial processes.

### BACKGROUNDS OF THE INVENTION

In the petrophysical evaluation of formations, well logs are used together with laboratory measurements of fluid, rock, and flow tests to characterize properties important for identifying hydrocarbon reservoirs and the corresponding petroleum system, supporting various aspects of the industry, such as the construction of geological models, quantification of reserves, and definition of production strategies. Among such properties, porosity, fluid saturation, permeability, mineral composition, and the presence of organic matter stand out.

Well logs, particularly those obtained by wireline geophysical tools or during drilling (logging while drilling, LWD), are essential for petrophysical evaluation because they are continuous records sensitive to different formation properties. One of these tools has a neutron source and a gamma radiation detector, hereinafter referred to as a nuclear spectroscopy tool. Such tools record the intensity of gamma photons as a function of their energies, called gamma spectra. The aforementioned radiation originates mainly from inelastic interactions and neutron capture by the atomic nuclei of the formation and the rest of the logging environment (tool, well fluid, well completion materials).

The gamma spectra undergo least squares fitting using standard elementary spectra, resulting in coefficients called relative yields (or simply yields). Among the chemical elements usually obtained by this processing, calcium (Ca), silicon (Si), iron (Fe), sulfur (S), titanium (Ti), magnesium (Mg), hydrogen (H) and chlorine (Cl) stand out. Subsequently, the yields of the elements predominantly present in the formation can be converted, by different methods, to elementary mass fractions (dry weights or weight fractions). The method described in U.S. Pat. No. 5,097,123A and subsequently elaborated on in U.S. Pat. No. 5,471,057A consists of an oxide closure model (hereinafter referred to simply as “closure”) widely used in industry even today. The closure involves selecting the measured elements whose yields are weighted by their respective sensitivity factors and stoichiometrically converted to the masses of oxides and carbonates that include elements not considered in the model. The sum of these parcels is normalized to unity by a multiplicative factor to be determined for each measurement, ensuring that the mass composition of the medium is completely described. If there are independent elementary measurements that are already in the desired mass fraction unit, the corresponding terms are added to the equation without being multiplied by the normalization factor.

Typically, the closures consider the chemical composition of the mineral constituents of rocks, in which elements such as Ca, Si, Mg, Fe, S, Ti are associated with oxygen (O) and carbon (C) forming oxides and carbonates, based on geochemically reasonable assumptions. The oxygen and carbon yields are not used directly because, although they are obtained with acceptable precision, there are no a priori ways to separate the well contribution from the formation signal, or the pore contribution from the inorganic rock signal. As an alternative, specifically for carbon, the technique of U.S. Pat. No. 9,851,468B2 allows, once the closure is made, the calculation of the corresponding mass fraction of carbon and, with the respective sensitivity factor, its conversion into the yield corresponding to the inorganic parcel. The difference between the total yield and the inorganic parcel will then be considered as being of organic origin, being subsequently converted into a mass fraction corresponding to total organic carbon (TOC).

In the literature on formation evaluation, it is common practice to combine information from different logs to estimate relevant properties of the formations, such as porosity, fluid saturations, mineral composition, and kerogen content. Such calculations may involve sequential solution of equations or the simultaneous solution of a system of equations involving the mixing functions for each property and the corresponding responses for each component in isolation. Depending on the specifics and the author, such models may be called “multimineral models,” “multiphysics models,” or generically “petrophysical models,” as will be adopted in the present document. It should be noted that such models are solved for each depth independently, with a step or sampling frequency arbitrarily defined based on the nature of the logs, typically defined as 0.1524 m (half a foot).

The chlorine (Cl) and hydrogen (H) signals are potentially important for the petrophysical characterization of the formations, given that chlorine is indicative of formation water content and hydrogen is present mainly in both water and hydrocarbons, both fluids and in the form of kerogen. Thus, it is possible that these elementary logs provide information that leads to better estimates of properties such as fluid saturation, salinity, hydrogen index (HI) of organic matter, among others. However, the use of the yields of these elements in closures incurs two challenges. The first is the difficulty in establishing an adequate closure that can accommodate the mass fractions of the fluids in the pores, i.e., the mineral closure alone is not sufficient. The second and most important challenge is how to separate the contribution of the well and the formation in the yields, given that in almost all situations the fluid present in the logging contains both elements.

Document US20160186556A1 proposes the use of a petrophysical model to estimate various mineral, fluid, and kerogen components of a formation using equations that represent the chemical compositions and the response functions of different well logs to the mentioned individual components. Among the logs used are the various elementary curves obtained by nuclear spectroscopy tools, including carbon, oxygen, hydrogen, and chlorine curves. The various components are calculated from a mathematical optimization that defines the volumetric proportion of the formation components that minimize the error related to measurements from the various logs. The document mentions the closure technique but does not explicitly state its use to convert yields into mass fractions in the specific application reported, only implying the use of a closure that takes into account both the mineral and fluid and kerogen composition of the formation. More importantly, the document does not provide any indication of how the parcels originating from the formation to the H and Cl yields are separated from the well contributions in the respective total signals.

Document U.S. Pat. No. 12,025,767B2 proposes a methodology for decomposing well and formation contributions to the yield of a given element by taking advantage of modifications in elementary spectra caused by gamma radiation scattering from different spatial regions. In particular, the document defines an elementary spectrum of the formation and a spectrum of the difference between well and formation. The document explores the methodology for the case of chlorine, using experimentally calibrated environmental corrections involving parameters such as well diameter, neutron porosity, and well fluid density, to convert measured yields into formation chlorine yield. The formation chlorine yield is then converted into a chlorine mass fraction relative to the mass of the dry rock using an equation involving the instrumental sensitivity to chlorine and the closure mineral normalization factor. Subsequently, this mass fraction can be used to obtain petrophysical parameters such as salinity and formation water saturation by combining the same with parameters such as total porosity and matrix density. Finally, the document explores the possibility of using these equations in petrophysical models integrating well log measurements such as sigma (macroscopic cross section of thermal neutron absorption), electrical dispersion, TOC, density, and porosity. The feasibility of applying said technique strongly depends on the environmental corrections that need to be made for each tool, requiring several detailed simulations or experiments, addition to systematic errors caused by deviations in the calibration function, the spectral differences as a function of the spectral distribution subtle, are very thus being susceptible to high uncertainties due to spectral inversion and errors caused by deviations in the elementary spectra caused by the well environment. Finally, the document does not incorporate hydrogen yield information into the proposed methodology.

Document U.S. Pat. No. 11,788,401B2 refers to an approach to determine oil saturation (So) in subsurface formations using geochemical measurements, combined with known or easily obtained characteristics of the geological formation in question. One of the challenges addressed by this technique is the difficulty in distinguishing between kerogen (insoluble organic material) and hydrocarbons in total organic carbon determinations. The method proposes the use of TOC, bulk density, matrix density, and porosity data obtained from well logs, in addition to the input of parameters such as kerogen, oil, and water densities in the subsurface formation or in one of its zones. Although document U.S. Pat. No. 11,788,401B2 presents features related to spectroscopy in well logs, there is no mention or suggestion of integrating total hydrogen and chlorine measurements to compose a petrophysical model. In addition, document U.S. Pat. No. 11,788,401B2 does not propose the use of nuclear spectroscopy with the purpose of improving petrophysical interpretation with the aforementioned elements.

It should be noted that there are several documents that propose petrophysical models to estimate properties such as salinity, TOC, amount and kerogen type, integrating different well logs. For example, document U.S. Pat. No. 11,187,825B2 describes a method and system for determining total porosity, saturation, and kerogen volume from density logs, porosity obtained by nuclear magnetic resonance (NMR), and TOC obtained by nuclear spectroscopy. The document U.S. Pat. No. 11,906,691B2 describes a method for improving the interpretation of neutron logs in subsurface formations by subtracting the contributions of solids from knowledge of mineralogy and the amount and content of kerogen at different depths, which can be obtained by petrophysical models with nuclear spectroscopy logs and laboratory results. These documents, as well as the state of the art, fail to simultaneously combine, in a petrophysical model, the chlorine and hydrogen measurements obtained by nuclear spectroscopy.

The objective of the invention is to propose a methodology for incorporating measurements of chlorine and hydrogen content, obtained from nuclear spectroscopy well logs, to enhance the petrophysical characterization of geological formations. When used appropriately, these elements provide relevant information about the content and salinity of formation water, fluid saturation, and kerogen content and its respective hydrogen index. In this way, the invention potentially contributes to a more detailed and robust analysis of the geological formations, improving the precision of models and better supporting decision-making in the hydrocarbon exploration and production chain that depends on the properties obtained in the petrophysical characterization.

### SUMMARY OF THE INVENTION

The present invention proposes a computer-implemented petrophysical modeling method that integrates data and interpretations of well nuclear spectroscopy with some input petrophysical parameters, decomposing hydrogen and chlorine yields into their specific origins, such as well drilling fluid, kerogen, water, and hydrocarbons in the pores. The model consists of a set of equations that are solved sequentially with input values defined by Monte Carlo simulation, from which properties such as salinity, porosity, density, sigma, and hydrogen index of the kerogen are calculated. The acceptability of such results is verified by comparison with logs such as density, NMR porosity, and sigma, in addition to respecting ranges of values considered physically reasonable for the evaluated well situation. This procedure generates statistical reliability metrics and allows the calculation of, among other properties, organic matter content and composition, salinity, and water saturation. The invention provides a detailed and statistically robust analysis of the geological composition, with applications in oil and gas exploration and production. Furthermore, the present invention relates to a computer-readable non-transient storage medium comprising instructions stored therein, wherein the instructions, when read by a computer, cause the computer to execute the steps of the method as defined above.

### BRIEF DESCRIPTION OF THE DRAWINGS

The present invention will now be described with reference to typical embodiments thereof and also with reference to the appended drawings, in which:

FIG. 1 is a flowchart of the steps of the method according to an embodiment of the present invention.

FIG. 2 is a representation of the results of the present invention applied to a case study, focusing on five main parameters: water saturation in the invaded zone, comparisons of the TOC with two alternative methods, the oil potential parameter (S2) and the hydrogen index of the kerogen.

FIG. 3 is a representation of the results related to the water saturation and salinity of the formation in the case study.

### DETAILED DESCRIPTION OF THE INVENTION

The computer-implemented petrophysical modeling method will be detailed below. The present invention can be divided into two layers. The first is the proposition of a set of equations that directly involve yields, called fundamental equations. The second consists of coupling these equations to another set of equations traditionally used in the industry and solving the same in a specific way, thus constituting a petrophysical model.

The objective of this innovation is to incorporate into the model the measurements of well spectroscopy logs related to chlorine (Cl) and hydrogen (H) content, adding relevant information for the characterization of the chemical composition and volumetric fractions of the different constituents of the formation.

The first equations express that the total yields of hydrogen Y_{H} and chlorine Y_{Cl} are made up of parcels of different origins. In the case of hydrogen (Eq. 1), the signal is made up of parcels originating from the well fluid

$$( {Y}_{H}^{bh} ) ,$$

water in the wells

$$( {Y}_{H}^{w} ) ,$$

hydrocarbon in the pores

$$( {Y}_{H}^{HC} ) ,$$

kerogen

$$( {Y}_{H}^{k erog} )$$

and mineral/inorganic

$$( {Y}_{H}^{min} ) .$$

In the case of chlorine (Eq. 2), the parcels originate from the well fluid

$$( {Y}_{Cl}^{b h} ) ,$$

water in the pores

$$( {Y}_{Cl}^{b h} )$$

and mineral

$$( {Y}_{Cl}^{min} ) .$$

$${Y}_{H} = {Y}_{H}^{b h} + {Y}_{H}^{w} + {Y}_{H}^{H C} + {Y}_{H}^{k e r o g} + {Y}_{H}^{min} \qquad ( 1 )$$

$${Y}_{Cl} = {Y}_{C l}^{b h} + {Y}_{C l}^{w} + {Y}_{Cl}^{min} \qquad ( 2 )$$

Equation (2) is expressed considering that the sign of the formation

$${Y}_{Cl}^{formation}$$

is the sum of the parcels

$${Y}_{Cl}^{w} + {Y}_{Cl}^{min} .$$

In the present invention, the following equation is applied separately to the salinities of the drilling fluid in the well SAL_{bh} (Eq. 3) and of the pore water SAL_{w} (Eq. 4).

$$\frac{1000}{S A {L}_{b h}} = 5.42 {R}_{s} \times \frac{{Y}_{H}^{b h}}{{Y}_{Cl}^{b h}} + 1 \qquad ( 3 )$$

$$\frac{1000}{S A {L}_{w}} = 5.42 {R}_{s} \times \frac{{Y}_{H}^{w}}{{Y}_{Cl}^{w}} + 1 \qquad ( 4 )$$

The factors Rₛ and

$${R}_{s}^{b h}$$

correspond to the ratio between the instrumental sensitivities for chlorine and hydrogen (s_{Cl}/s_{H}) in the formation and in the well, respectively. These values are tool-dependent, or can be estimated through computer simulations that depend on the detailed design of the tool.

The elementary sensitivities sᵢ can be provided by the companies that own the tools and, in certain cases, can be obtained by a simple back-analysis of real logs provided by these companies.

The use of closure models to obtain the elementary composition of the mineral parcel of the formation has been made since the 1980s and has subsequently been implemented in most modern tools. Its simplest form is represented in Eq. (5), wherein the yields Yᵢ are derived from the gamma spectrum obtained by tools with a chemical neutron source. The parameters Xᵢ are stoichiometric factors that typically convert the mass of the element into the mass of the oxide or carbonate to which they are hypothetically associated.

$${F}_{min} \times \{ {\sum }_{i}^{min} \frac{{Y}_{i}}{{s}_{i}} {X}_{i} \} = 1 \qquad ( 5 )$$

When using pulsed neutron tools, as is the case in the present invention, for which two spectra are typically obtained (one with a predominance of gammas from inelastic interactions and the other predominantly from capture), a specific treatment needs to be applied to reconcile the mass fractions derived from the different spectra. Still, it is possible to express the result as a single closure in the form of Eq. (5), by combining inelastic and capture terms. If there are elementary measurements that are not obtained by the induced gamma spectrum, the corresponding terms must be outside the normalization.

The potassium mass fraction K_{GRspec} is obtained by the natural gamma log with an absolute calibration, independently of the nuclear spectroscopy with neutron source. This value can optionally be included in the closure in the form of Eq. (6), with the potassium yield not entering into the closure summation:

$${K}_{GRspec} {X}_{K , K 2 O} + {F}_{min} \times \{ {{\sum }_{i}}^{min} \frac{{Y}_{i}}{{s}_{i}} {X}_{i} \} = 1 \qquad ( 6 )$$

The conversion of the yields used into mass fractions (dry weights) in this closure is given by Eq. (7):

$$D {W}_{i}^{min} = {F}_{min} \times \frac{{Y}_{i}}{{s}_{i}} \qquad ( 7 )$$

In addition to the mineral constituents, the solid part of the formation may further be composed of kerogen. To differentiate the two situations, a solids closure can be defined by adding the corresponding terms. The main chemical component of kerogen is carbon, whose mass fraction in the solids is referred to in the literature as “total organic carbon” (TOC), here expressed in grams of organic carbon per gram of rock.

TOC can be obtained either from the spectroscopy log itself or from methods independent of the spectroscopy. Assuming that the TOC has been calculated by an independent source, the closure of the formation can be approximated by Eq. (8):

$${K}_{GRspec} {X}_{K , K 2 O} + TOC + {F}_{s o l} \times \{ {\sum }_{i}^{min} \frac{{Y}_{i}}{{s}_{i}} {X}_{i} + \frac{{Y}_{H}^{k e r o g}}{{s}_{H}} {X}_{H k} \} = 1 \qquad ( 8 )$$

Where X_{Hk} is the stoichiometric factor that complements the content of other elements present in kerogen, mainly oxygen and sulfur.

The hydrogen fraction originating from kerogen is given, in analogy to Eq. (7), by:

$$D {W}_{H}^{s o l} = {F}_{s o l} \times \frac{{Y}_{H}^{k e r o g}}{{s}_{H}} \qquad ( 9 )$$

from which the oil potential S2 can be calculated:

$$S 2 = \frac{D {W}_{H}^{s o l}}{0.17} \times 1000 \qquad ( 10 )$$

and, subsequently, the hydrogen index of the organic matter HI_{kerog}:

$${HI}_{k e r o g} = \frac{S 2}{TOC} \qquad ( 11 )$$

the mass fraction of kerogen DW_{kerog} in the solid part is given by:

$${DW}_{kerog} = TOC + {DW}_{H}^{sol} \times {X}_{Hk} \qquad ( 12 )$$

The formation closure can be rewritten to include the terms referring to fluids in the pores. Simplifying the composition of water in the formation as an aqueous solution of NaCl and the oil/gas as hydrocarbons of composition CₓH_{y}, there is the following equation:

$${F}_{form} [ {\sum }_{i}^{min} \frac{{Y}_{i}}{{s}_{i}} {X}_{i} + \frac{{Y}_{H}^{kerog}}{{s}_{H}} + {\sum }_{j}^{fluid} \frac{{Y}_{j}}{{s}_{j}} {X}_{j} ] + \frac{{ρ}_{s} ( 1 - ϕ )}{{ρ}_{b}} [ {K}_{GRspec} {X}_{K , {K}_{2} O} + COT ] = 1 \qquad ( 13 )$$

$$where$$

$${\sum }_{j}^{fluid} \frac{{Y}_{j}}{{s}_{j}} {X}_{j} = \frac{{Y}_{H}^{w}}{{s}_{H}} {X}_{H , {H}_{2} O} + \frac{{Y}_{H}^{HC}}{{s}_{H}} {X}_{H , HC} + \frac{{Y}_{Cl}^{w}}{{s}_{Cl}} {X}_{Cl , NaCl} \qquad ( 14 )$$

The water content is obtained from the term involving

$${Y}_{H}^{w}$$

in Eq. (13); sodium chloride is obtained from the term involving

$${Y}_{Cl}^{w} ;$$

and Hydrocarbons are obtained from the term

$${Y}_{H}^{HC} ,$$

weighted by the stoichiometric factor X_{H,HC} defined numerically by the composition CₓH_{y}. This closure can be written as a function of the mass fraction of solids Mₛ and fluids M_{fl}, given respectively by Eqs. (15) and (16), such that Mₛ+M_{fl}=1:

$${M}_{s} = {F}_{form} [ {\sum }_{i}^{min} \frac{{Y}_{i}}{{s}_{i}} {X}_{i} + \frac{{Y}_{H}^{kerog}}{{s}_{H}} ] + \frac{{ρ}_{s} ( 1 - {ϕ}_{T} )}{{ρ}_{b}} [ {K}_{GRspec} {X}_{K , {K}_{2} O} + TOC ] \qquad ( 15 )$$

$${M}_{fl} = {F}_{form} {\sum }_{j}^{fluid} \frac{{Y}_{j}}{{s}_{j}} {X}_{j} \qquad ( 16 )$$

Since the mass fractions of solids and fluids are defined, the total porosity φ_{T} of the formation can be written as:

$${ϕ}_{T} = \frac{\frac{{M}_{fl}}{{ρ}_{fl}}}{\frac{{M}_{fl}}{{ρ}_{fl}} + \frac{{M}_{s}}{{ρ}_{s}}} \qquad ( 17 )$$

Where ρ_{fl} and ρₛ correspond, respectively, to the specific masses of the fluids and solids, to be defined later in the petrophysical model. Rewriting the terms of Eq. (14) as χ_{w}, χ_{HC} and χ_{NaCl}, the water saturation S_{w} is given by Eq. (18):

$${S}_{w} = \frac{\frac{( {χ}_{w} + {χ}_{Na cl} )}{{ρ}_{w}}}{\frac{{χ}_{HC}}{{ρ}_{HC}} + \frac{( {χ}_{w} + {χ}_{NaCl} )}{{ρ}_{w}}} \qquad ( 18 )$$

Complementing the previous equations (Eqs. 1 to 18), the proposed petrophysical model further includes the following equations, their use being optional, depending on the type and degree of precision of the model applied:

Specific mass of solids (Eq. 19): involves the mineral specific mass ρₘᵢₙ, the kerogen specific mass ρ_{kerog} and the mass fraction of the kerogen DW_{kerog} from Eq. (12).

Specific gravity of brine NaCl (Eq. 20): a function that calculates the specific gravity of water as a function of salinity SAL_{w}, pressure p, and temperature T.

Specific gravity of filtrate (Eq. 21): a function that calculates the specific gravity of the filtrate as a function of its composition, pressure, and temperature.

Specific gravity of hydrocarbons (Eq. 22): calculates the specific gravity of hydrocarbons based on composition, pressure, and temperature.

Specific gravity the fluids in the formation (Eq. 23): weights the densities of water, hydrocarbons, and filtrate as a function of the water saturation of the virgin zone S_{w} and the invasion factor fᵢₙᵥ.

Bulk density (Eq. 24): calculates the density of the formation based on the densities of solids and fluids weighted by total porosity.

Macroscopic thermal absorption (Eq. 25): calculates the macroscopic cross section of thermal neutron absorption for each component (water, hydrocarbon, filtrate, solids), based on the elementary mass fractions fᵢⱼ and the mass absorption coefficients μⱼ.

Macroscopic thermal absorption of the formation (Eq. 26): calculates the macroscopic cross section of thermal neutron absorption of the formation by volumetrically combining the Σᵢ of the components, considering the position relative to the oil/water contact.

$${ρ}_{s} = \frac{{ρ}_{min} \times {ρ}_{kerog}}{( 1 - {DW}_{kerog} ) \times {ρ}_{kerog} + {DW}_{kerog} \times {ρ}_{min}} \qquad ( 19 )$$

$${ρ}_{w} = {g}_{w} ( T , p , {SAL}_{w} ) \qquad ( 20 )$$

$${ρ}_{filt} = {g}_{filt} ( T , p , composition ) \qquad ( 21 )$$

$${ρ}_{HC} = {g}_{HC} ( T , p , composition ) \qquad ( 22 )$$

$${ρ}_{fl} = {S}_{w} {ρ}_{w} + ( 1 - {S}_{w} ) {f}_{inv} {ρ}_{filt} + ( 1 - {S}_{w} ) ( 1 - {f}_{inv} ) {ρ}_{HC / w} \qquad ( 23 )$$

$${ρ}_{b} = {ϕ}_{T} {ρ}_{fl} + ( 1 - {ϕ}_{T} ) {ρ}_{s} \qquad ( 24 )$$

$${\sum }_{i} = {ρ}_{i} ( {\sum }_{j}^{elem} {f}_{ij} {μ}_{ij} ) \times 1000 \qquad ( 25 )$$

$${\sum }_{f} = ( 1 - ϕ ) {\sum }_{sol} + ϕ {S}_{w} {\sum }_{w} ϕ ( 1 - {S}_{w} ) {f}_{inv} {\sum }_{filt} + ϕ ( 1 - {S}_{w} ) ( 1 - {f}_{inv} ) {\sum }_{HC / w} \qquad ( 26 )$$

Other petrophysical equations can be coupled to the model, involving properties that are sensitive to other logs or even equations related to the chemical composition of minerals and elementary mass fractions.

When considering the set of equations as presented, in most practical situations the number of unknowns to be calculated is greater than the dimension of the system, that is, it is an indeterminate system. The usual approach to this type of problem involves the use of optimization methods to find solutions that minimize the error, based on a definition of cost function. However, the search for an optimal solution ends up not adequately considering the multiplicity of acceptable responses within a certain margin of error, and this multiplicity carries the important information of uncertainty of the responses. Accordingly, a possible approach is to use Monte Carlo (MC) simulations to adequately scan the space of the variables and identify the set of acceptable solutions for the model, within a given tolerance.

### Modeling Method

In general terms, the petrophysical modeling method by analyzing nuclear well spectroscopy logs comprises the following steps:
a. receiving curves of potassium content, saturation of water and total organic carbon, as well as kerogen density and invasion factor;
b. receiving elementary yields from spectroscopy logs, including hydrogen (Y_{H}) and chlorine (Y_{Cl}) yields, as well as information on fluid and kerogen properties, mineral density, well pressure and temperature;
c. defining a closure for the formation (F_{form}) according to the equation

$${F}_{form} [ {\sum }_{i}^{min} \frac{{Y}_{i}}{{s}_{i}} {X}_{i} + \frac{{Y}_{H}^{kerog}}{{s}_{H}} + {\sum }_{j}^{fluid} \frac{{Y}_{j}}{{s}_{j}} {X}_{j} ] + \frac{{ρ}_{s} ( 1 - ϕ )}{{ρ}_{b}} [ {K}_{GRspec} {X}_{K , {K}_{2} O} + TOC ] = 1$$

$$where$$

$${\sum }_{j}^{fluid} \frac{{Y}_{j}}{{s}_{j}} {X}_{j} = \frac{{Y}_{H}^{w}}{{s}_{H}} {X}_{H , {H}_{2} O} + \frac{{Y}_{H}^{HC}}{{s}_{H}} {X}_{H , HC} + \frac{{Y}_{Cl}^{w}}{{s}_{Cl}} {X}_{Cl , Naci} ;$$

wherein

$${Y}_{H}^{w} , {Y}_{H}^{HC} and {Y}_{H}^{kerog}$$

are respectively the hydrogen yield parcels corresponding to formation water, hydrocarbon and kerogen,

$${Y}_{Cl}^{w}$$

is the chlorine yield parcel corresponding to formation water, S_{H} and S_{Cl} are the instrumental sensitivities to H and Cl by the capture spectrum, ρₛ is the solids density, ρ_{b} is the bulk density of the formation, K_{GRspec}X_{K,K}_{₂}_{O} is the potassium oxide mineral content and TOC is the total organic carbon fraction of the rock;
d. defining fluid mass fractions M_{fl} and solids mass fractions Mₛ at the base of the formation from the closure as:

$$\begin{matrix}{M}_{fl} = {F}_{form} {\sum }_{j}^{fluid} \frac{{Y}_{j}}{{s}_{j}} {X}_{j} \\ {M}_{s} = {F}_{form} [ \frac{1}{{F}_{min}} + \frac{{Y}_{H}^{kerog}}{{s}_{H}} ] + \frac{{ρ}_{s} ( 1 - {ϕ}_{T} )}{{ρ}_{b}} [ {K}_{GRspec} {X}_{K , {K}_{2} O} + TOC ]\end{matrix}$$

where Fₘᵢₙ is the normalization factor of the mineral closure and φ_{T} is the total porosity of the formation;
e. defining the total porosity φ_{T} and water saturation
   S_{w} from the equations

$$\begin{matrix}{ϕ}_{T} = \frac{\frac{{M}_{fl}}{{ρ}_{fl}}}{\frac{{M}_{fl}}{{ρ}_{fl}} + \frac{{M}_{s}}{{ρ}_{s}}} \\ {S}_{w} = \frac{\frac{( {χ}_{w} + {χ}_{Na cl} )}{{ρ}_{w}}}{\frac{{χ}_{HC}}{{ρ}_{HC}} + \frac{( {χ}_{w} + {χ}_{NaCl} )}{{ρ}_{w}}}\end{matrix}$$

wherein ρ_{w}, ρ_{HC} and ρ_{fl} are respectively the densities of water, hydrocarbon and total fluid in the pores, χ_{w}, χ_{NaCl} and χ_{HC} correspond respectively to the terms

$$\begin{matrix}{Y}_{H}^{w} / {s}_{H} {X}_{H , {H}_{2} O} , \\ {Y}_{H}^{HC} / {s}_{H} {X}_{H , HC} and {Y}_{Cl}^{w} / {s}_{Cl} {X}_{Cl , NaCl} ;\end{matrix}$$

f. including in the model equations commonly used in petrophysics for calculating the specific gravity of solids, specific gravity of NaCl brine, specific gravity of filtrate, specific gravity of hydrocarbons, specific gravity of the fluids in the formation, bulk density from the specific gravities of solids and fluids, in addition to other optional equations such as macroscopic thermal absorption of fluids, solids and the formation, depending on additional logs to be used;
g. drawing values for properties and input curves (composition and density of fluids and kerogen, elementary yields obtained from the logs, potassium, mineral density, saturation, invasion factor, well pressure and temperature) by applying the Monte Carlo method;
h. solving the model equations sequentially and calculating verification properties, including total porosity, bulk density and macroscopic cross section of thermal neutrons of the formation;
i. comparing the verification properties with the corresponding logs, storing the properties of interest when the differences between the verification properties and the corresponding logs are equal to or less than the predefined tolerances;
j. generating statistical and graphical inferences of properties such as TOC, S2, hydrogen index of the kerogen, formation water salinity, and water saturation;
k. repeating steps (g) to (j) for each depth step.

More specifically, in order to map the set of acceptable solutions by Monte Carlo simulations from petrophysically interpretable input and verification information, the system resolution method was implemented using three sets of information:
(i) Input information—T, p, SAL_{w}, SAL_{bh}, S_{w}, Y_{H}, Y_{Cl}, ρ_{kerog}, TOC, K, fᵢₙᵥ, other yields of the mineral closure. ρₘᵢₙ must be previously calculated by a mineral model, or have its value arbitrarily assumed based on the lithology;
(ii) Complementary information-chemical composition of the filtrate, hydrocarbon and water, position of the oil/water contact, elementary instrumental sensitivities and fluid density models (Eqs. (20), (21), (22));
(iii) Information for consistency verification—φ_{T}, ρ_{b}, Σ_{f} logs.

Input information can be provided in distributions (constant values, uniform interval, triangular or normal distributions, for example) or in curves with estimated uncertainties. This data can be obtained from logs, experimental measurements, or ranges of values to be tested, depending on the application. In each Monte Carlo simulation, a value will be drawn for each input, considering the provided distribution.

In an implementation, the following calculations will be performed for each simulation:
(i) Calculating the ratio between hydrogen and chlorine yields for the fluid in the well (r_{bh}) and in the formation (r_{w}), isolating the corresponding term in Eqs. 3 and 4;
(ii) Calculating the mass densities ρ_{w}, ρ_{filt} and ρ_{HC} Of the fluids in the pores, respectively by equations 20, 21, and 22;
(iii) Calculating the absorption cross sections Σ_{w}, Σ_{filt} and Σ_{HC} by using Eq. 25 with the respective chemical compositions and mass densities;
(iv) Calculating the fluid density in the pores pa by using Eq. 23, considering the type of drilling fluid and the position relative to the oil/water contact;
(v) Calculating

$${( {Y}_{H}^{kerog} )}^{max}$$

from Eq. 27, which is a combination of Eqs. 9, 10 and 11 assuming a geochemically reasonable maximum value

$${HI}_{kerog}^{max}$$

for the hydrogen index of the kerogen, around 1000-1200. The value of

$${Y}_{H}^{kerog}$$

is drawn from a uniform distribution between zero and

$${( {Y}_{H}^{kerog} )}^{max} ;$$

$${( {Y}_{H}^{kerog} )}^{max} = \frac{0.17 {HI}_{kerog}^{max}}{1000} \times TOC \times \frac{{s}_{H}}{{F}_{sol}} \qquad ( 27 )$$

(vi) Calculating

$${Y}_{Cl}^{bh}$$

by Eq. 28, where Ω is given by Eq. 29. These equations are obtained by algebraic manipulation of Eqs. 1, 2, 3, 4 and 18, assuming

$${Y}_{H}^{min} = 0 and {Y}_{Cl}^{min} = 0 ;$$

$${y}_{Cl}^{bh} = \frac{{Y}_{H} - {Y}_{H}^{MO} - {Y}_{Cl} ( {r}_{w} + Ω )}{{r}_{bh} - {r}_{w} - Ω} \qquad ( 28 )$$

$$Ω = ( \frac{1}{{S}_{w}} - 1 ) \times \frac{{ρ}_{hc}}{{ρ}_{w} {X}_{H , hc}} \times ( {r}_{w} {X}_{H , {H}_{2} O} + \frac{{s}_{H}}{{s}_{Cl}} {X}_{Cl , NaCl} ) \qquad ( 29 )$$

(vii) Obtaining

$${Y}_{Cl}^{w}$$

from Eq. 2, assuming

$${Y}_{Cl}^{min} = 0.$$

If

$${Y}_{Cl}^{w} < 0 ,$$

the simulation is considered invalid and is then interrupted;
(viii) Obtaining

$${Y}_{H}^{bh} and {Y}_{H}^{w}$$

by manipulating Eqs. 3 and 4, respectively;
(ix) Obtaining

$${Y}_{H}^{HC}$$

from Eq. 30, resulting from the algebraic manipulation of Eqs. 1-4 and 28;

$${Y}_{H}^{HC} = ( {Y}_{Cl} - {Y}_{Cl}^{bh} ) \times Ω \qquad ( 30 )$$

(x) Explicitly calculating the term

$${\sum }_{i}^{min} {Y}_{i} / {s}_{i} {X}_{i}$$

by using (x) Explicitly calculating the term the yields or from 1/Fₘᵢₙ (Eq. 5), assuming that Fₘᵢₙ has been processed and delivered by the service company using the corresponding equation;
(xi) Calculating Fₛₒₗ by using Eq. 8;
(xii) Calculating

$${DW}_{H}^{sol} ,$$

S2, HI_{kerog}, DW_{kerog} and ρₛ respectively by using Eqs. 9, 10, 11, 12 and 19;
(xiii) Defining an initial estimate for porosity (e.g., φ_{T}=1); sequentially calculating ρ_{b}, F_{form} and φ_{T} respectively by using Eqs. 24, 13, and 17; repeating this process until the numerical convergence of the total porosity;
(xiv) Calculating τ_{f} using Eq. 26.

For consistency verification, the calculated values for verification properties φ_{T}, ρ_{b} and Σ_{f} should be compared with the respective log measurements. If the absolute value of the difference between the measured and calculated properties is less than a user-defined limit, the simulation is considered valid, and the results of the input parameters of the properties of interest are stored for later evaluation.
(i) The porosity log to be used must be independent of ρ_{b}; the log normally used is that obtained by nuclear magnetic resonance;
(ii) The use of the τ_{f} property is optional, depending on the availability of this log.

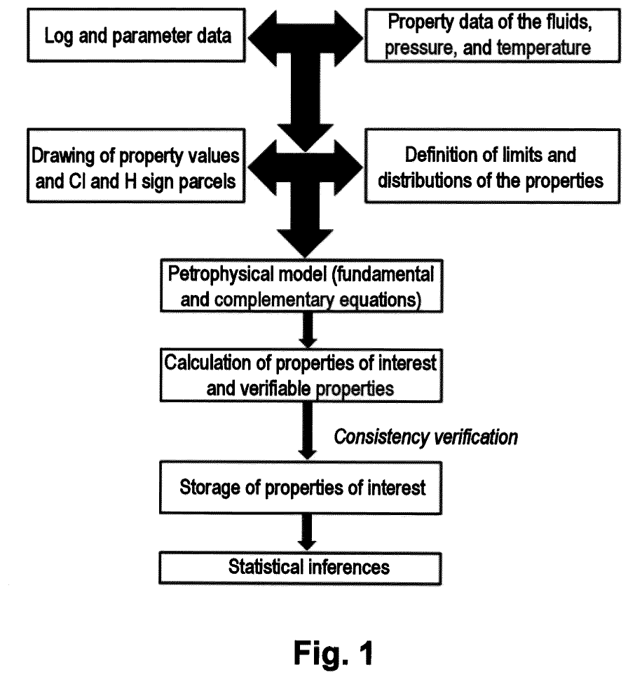

In simplified terms, the main steps of the method implementation are shown in FIG. 1.

Several MC simulations (typically 10³-10⁵) are run for each depth step, resulting in valid value distributions for the inputs and properties of interest, on which statistical metrics such as mean and median are made, in addition to cumulative probability curves according to the desired significance level (e.g., P10 and P90 curves for the significance level α=0.1), which indicate the uncertainty of the estimates.

In order to simplify the calculations and avoid numerical instabilities, when the TOC content is below a minimum limit (e.g., TOC<0.05%), the kerogen content is considered to be zero.

In addition to the simplifications

$${Y}_{H}^{min} = 0 and {Y}_{Cl}^{min} = 0 ,$$

other simplifications are implicit in the calculations:
(i) The pressure and temperature input curves are considered constant for the purposes of calculating the specific masses ρ_{w}, ρ_{filt} and ρ_{HC};
(ii) It is assumed that the ratio between the sensitivities of H and Cl for the well (Eq. 3) is equal to that of the formation (Eq. 4);
(iii) It is assumed that the stoichiometric proportion of hydrogen, sulfur, and oxygen in the kerogen is constant, i.e., χ_{Hk}=cte in Eq. 13;
(iv) The equations must be adapted for the case of the coexistence of hydrocarbons in the liquid and gaseous phases in the formation.

The proposed system is also valid for the presence of CO₂ in the formation, with the necessary adjustments to the compositions (including the absence of hydrogen in the composition) and equations of state.

### Application of the Modeling Method

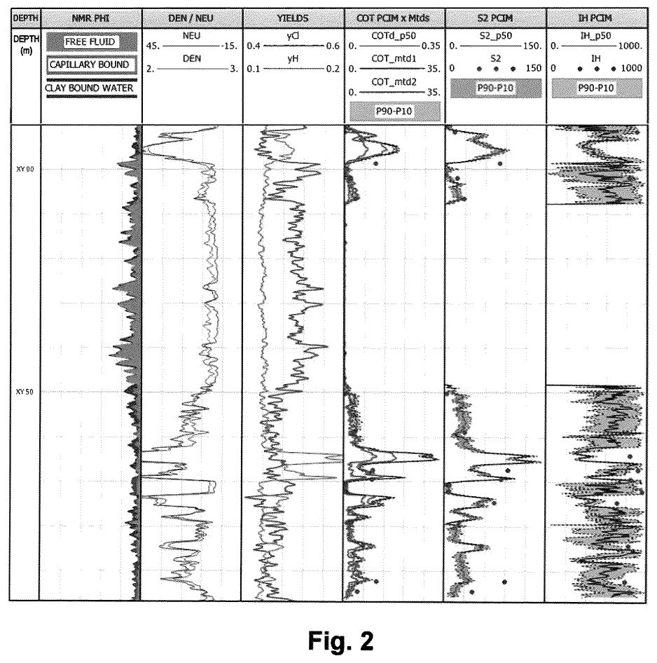

For illustrative purposes, a case study was conducted on a marine well off the Brazilian coast. In this well, the input data for total porosity, saturation, density, potassium, and elementary yields were measured by the respective well tools (nuclear magnetic resonance, density with source, natural gamma spectroscopy, and induced gamma spectroscopy, respectively) and sent to a computational device that executes the modeling method now proposed. FIG. 2 presents the results for an interval with hydrocarbon generation potential. In the three rightmost tracks, from left to right, there are presented: TOC estimates by the present method compared to alternative methods; S2 and hydrogen index. The curves shown in this way characterize the presence and the content of organic carbon, the generation potential, and the quality of the kerogen present in the subsurface, in good agreement with available experimental data indicated by purple points.

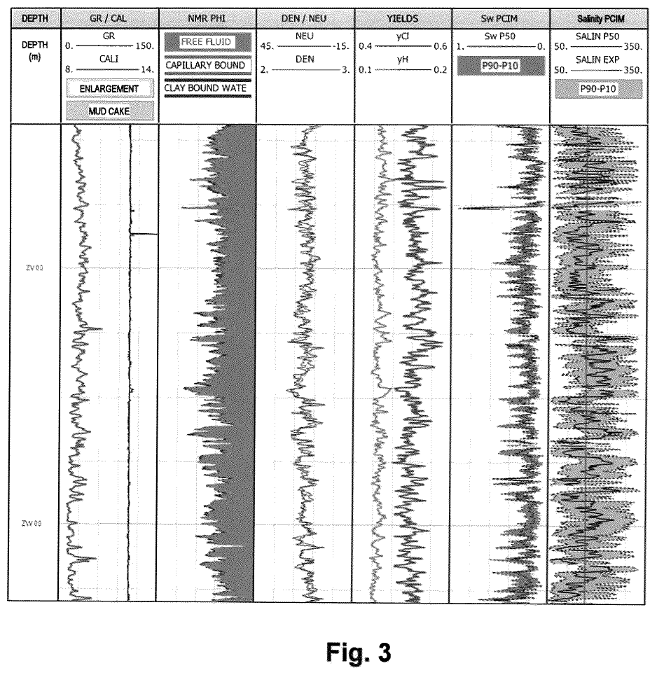

FIG. 3 presents the results obtained with the present invention for water saturation and salinity for another interval of the same case study cited above. In the penultimate track on the right, the range of saturations Sw obtained in the invaded zone is presented; in the last one, the salinity range for the formation water, whose average experimental value for the well is indicated by a constant red line. Despite the high uncertainties, it can be considered that the average value of the formation water salinity estimates for the interval is qualitatively in agreement with the experimental value.

Finally, in another embodiment of the present invention, a computer-readable non-transient medium is provided. The medium can be, for example, a memory, a flash memory, a hard disk, a compact disk, or any other device capable of storing computer instructions. When the readable medium of the present embodiment is read by a computer, the computer is enabled to perform the petrophysical modeling method.

1. A computer-implemented method for petrophysical modeling by analyzing nuclear spectroscopy logs of wells, wherein the method comprises:
a. receiving curves of potassium content, saturation of water and total organic carbon, as well as kerogen density and invasion factor;
b. receiving elementary yields from spectroscopy logs, including hydrogen (Y_{H}) and chlorine (Y_{Cl}) yields, as well as information on fluid and kerogen properties, mineral density, well pressure and temperature;
c. defining a closure for the formation (F_{form}) according to the equation
$${F}_{form} [ {\sum }_{i}^{min} \frac{{Y}_{i}}{{s}_{i}} {X}_{i} + \frac{{Y}_{H}^{kerog}}{{s}_{H}} + {\sum }_{j}^{fluid} \frac{{Y}_{j}}{{s}_{j}} {X}_{j} ] + \frac{{ρ}_{s} ( 1 - ϕ )}{{ρ}_{b}} [ {K}_{GRspec} {X}_{K , {K}_{2} O} + TOC ] = 1$$
$$where$$
$${\sum }_{j}^{fluid} \frac{{Y}_{j}}{{s}_{j}} {X}_{j} = \frac{{Y}_{H}^{w}}{{s}_{H}} {X}_{H , {H}_{2} O} + \frac{{Y}_{H}^{HC}}{{s}_{H}} {X}_{H , HC} + \frac{{Y}_{Cl}^{w}}{{s}_{Cl}} {X}_{Cl , NaCl} ;$$
wherein
$${Y}_{H}^{w} , {Y}_{H}^{HC} and {Y}_{H}^{kerog}$$
are respectively the hydrogen yield parcels corresponding to formation water, hydrocarbon and kerogen,
$${Y}_{Cl}^{w}$$
is the chlorine yield parcel corresponding to formation water, s_{H} and s_{Cl} are the instrumental sensitivities to H and Cl by the capture spectrum, ρₛ is the solids density, ρ_{b} is the bulk density of the formation, K_{GRspec}X_{K,K}_{₂}_{O} is the potassium oxide mineral content and TOC is the total organic carbon fraction of the rock;
d. defining fluid mass fractions M_{fl} and solids mass fractions Mₛ at the base of the formation from the closure as:
$${M}_{fl} = {F}_{form} {\sum }_{j}^{fluid} \frac{{Y}_{j}}{{s}_{j}} {X}_{j}$$
$${M}_{s} = {F}_{form} [ \frac{1}{{F}_{min}} + \frac{{Y}_{H}^{kerog}}{{s}_{H}} ] + \frac{{ρ}_{s} ( 1 - {ϕ}_{T} )}{{ρ}_{b}} [ {K}_{GRspec} {X}_{K , {K}_{2} O} + TOC ]$$
where Fₘᵢₙ is the normalization factor of the mineral closure and φ_{T} is the total porosity of the formation;
e. defining the total porosity φ_{T} and water saturation S_{w} from the equations
$${ϕ}_{T} = \frac{\frac{{M}_{fl}}{{ρ}_{fl}}}{\frac{{M}_{fl}}{{ρ}_{fl}} + \frac{{M}_{s}}{{ρ}_{s}}}$$
$${S}_{w} = \frac{\frac{( {χ}_{w} + {χ}_{NaCl} )}{{ρ}_{w}}}{\frac{{χ}_{HC}}{{ρ}_{HC}} + \frac{( {χ}_{w} + {χ}_{NaCl} )}{{ρ}_{w}}}$$
wherein ρ_{w}, ρ_{HC} and ρ_{fl} are respectively the densities of water, hydrocarbon and total fluid in the pores, χ_{w}, χ_{NaCl} and χ_{HC} correspond respectively to the terms
$${Y}_{H}^{w} / {s}_{H} {H}_{H , {H}_{2} O} , {Y}_{H}^{HC} / {s}_{H} {H}_{H , H C} and {Y}_{Cl}^{w} / {s}_{Cl} {H}_{Cl , NaCl} ;$$
f. including in the model equations for calculating the specific gravity of solids, specific gravity of the NaCl brine, specific gravity of the filtrate, specific gravity of hydrocarbons, specific gravity of fluids in the formation, bulk density from the specific gravities of solids and fluids, in addition to other optional equations such as macroscopic thermal absorption of the fluids, solids, and the formation, depending on additional logs to be used;
g. drawing values for properties and input curves (composition and density of fluids and kerogen, elementary yields obtained from the logs, potassium, mineral density, saturation, invasion factor, well pressure and temperature) by applying the Monte Carlo method;
h. solving the model equations sequentially and calculating verification properties, including total porosity, bulk density and macroscopic cross section of thermal neutrons of the formation;
i. comparing the verification properties with the corresponding logs, storing the properties of interest when the differences between the verification properties and the corresponding logs are equal to or less than the predefined tolerances;
j. generating statistical and graphical inferences of properties such as TOC, S2, hydrogen index of the kerogen, formation water salinity, and water saturation;
k. repeating steps (g) to (j) for each depth step.

2. The method according to claim 1, wherein in step (g), the Monte Carlo simulation process includes:
(i) selecting a hydrogen yield value for kerogen
$$( {Y}_{H}^{kerog} )$$
according to a specific limited distribution whose upper limit is calculated from a predefined maximum value of the hydrogen index of the organic matter
$${HI}_{kerog}^{max} ;$$
(ii) selecting values for the input properties and curves according to predefined probability distributions based on the nature of each data point.

3. The method according to claim 1, wherein the predefined tolerances T are defined as:
$$\vert {ϕ}_{T} - {ϕ}_{T}^{calc} \vert \leq {T}_{{ϕ}_{T}}$$
$$\vert {ρ}_{b} - {ρ}_{b}^{calc} \vert \leq {T}_{{ρ}_{b}}$$
$$\vert {\sum }_{f} - {\sum }_{f}^{calc} \vert \leq {T}_{{\sum }_{f}}$$
where
$${ϕ}_{T}^{calc} , {ρ}_{b}^{calc} and {\sum }_{f}^{calc}$$
are calculated values for, respectively, total porosity, bulk density and macroscopic thermal absorption of the formation; and T_{φT}, T_{ρb} and T_{Σf} are previously defined tolerance values.

4. The method according to claim 1, wherein for each depth step, the following is calculated:
ratio between hydrogen and chlorine yields for the fluid in the well (r_{bh}) and in the formation (r_{w});
mass densities ρ_{w}, ρ_{filt} and ρ_{HC} of the fluids in the pores;
absorption cross sections Σ_{w}, Σ_{filt} and Σ_{HC};
density of fluids in the pores (ρ_{fl});
upper limit of the hydrogen yield parcel from kerogen
$${( {Y}_{H}^{kerog} )}^{max} ;$$
chlorine yield parcel from the fluid in the well
$${y}_{Cl}^{bh} ;$$
chlorine yield parcel from the water in the formation
$${Y}_{Cl}^{w} ;$$
hydrogen yield parcel from the fluid in the well
$${Y}_{H}^{b h}$$
and from the weather in the formation
$${Y}_{H}^{w} ;$$
hydrogen yield parcel from hydrocarbons in the formation
$${Y}_{H}^{H C} ;$$
sum of the components of the mineral closure
$${\sum }_{i}^{min} {Y}_{i} / {s}_{i} {X}_{i} ;$$
normalization factor of the solids closure Fₛₒₗ;
hydrogen mass fraction at the base of the solids
$$D {W}_{H}^{s o l} ,$$
oil generation potential S2, hydrogen index of the kerogen HI_{kerog}, mass fraction of the kerogen DW_{kerog} and solids density ρₛ;
normalization factor of the closure of the formation F_{form}, bulk density of the formation pp and total porosity φ_{T};
macroscopic section of thermal neutron absorption of the formation Σ_{f}.

5. The method according to claim 4, wherein the calculation of
$${( {Y}_{H}^{k e r o g} )}^{max}$$
comprises:
$${( {Y}_{H}^{k e r o g} )}^{max} = \frac{0.17 {H I}_{k e r o g}^{max}}{1000} \times TOC \times \frac{{s}_{H}}{{F}_{s o l}}$$
wherein
$${H I}_{k e r o g}^{max}$$
is the maximum hydrogen content allowed for the kerogen.

6. The method according to claim 4, wherein the calculation of
$${Y}_{c l}^{b h}$$
comprises:
$${Y}_{c l}^{b h} = \frac{{Y}_{H} - {Y}_{H}^{M O} - {Y}_{C l} ( {r}_{w} + Ω )}{{r}_{b h} - {r}_{w} - Ω} ,$$
wherein Ω is a parameter calculated by the equation
$$Ω = ( \frac{1}{{s}_{w}} - 1 ) \times \frac{{p}_{h c}}{{ρ}_{w} {X}_{H , hc}} \times ( {r}_{w} {X}_{H , {H}_{2} O} + \frac{{s}_{H}}{{s}_{C l}} {X}_{Cl , NaCl} ) .$$

7. The method according to claim 4, wherein the calculation of
$${y}_{H}^{H C}$$
comprises:
$${Y}_{H}^{{HC}_{=}} ( {Y}_{C l} - {Y}_{C l}^{b h} ) \times Ω .$$

8. The method according to claim 4, wherein the calculation of the term
$${\sum }_{i}^{min} {Y}_{i} / {s}_{i} {X}_{i}$$
is done from the elementary yields or from 1/Fₘᵢₙ, wherein:
$${F}_{min} \times \{ {{\sum }^{min}}_{i} \frac{{Y}_{i}}{{s}_{i}} {X}_{i} \} = 1$$

9. The method according to claim 4, wherein the calculation of de ρ_{b}, F_{form} and φ_{T} comprises defining an initial value for porosity and iteratively reducing the same until reaching the numerical convergence of the total porosity.

10. A computer-readable non-transient storage medium comprising instructions stored thereon, wherein the instructions, when read by a computer, cause the computer to execute the steps of the method as defined in claim 1.
